(19) United States
(12) Patent Application Publication
(10) Pub. No.: US 2025/0125773 A1
(43) Pub. Date: Apr. 17, 2025

(54) RADIO FREQUENCY CIRCUIT PROVIDING TEMPERATURE COMPENSATION

(71) Applicant: RichWave Technology Corp., Taipei City (TW)

(72) Inventor: Po-Hsiang Yang, Taipei City (TW)

(73) Assignee: RichWave Technology Corp., Taipei City (TW)

(21) Appl. No.: 18/393,725

(22) Filed: Dec. 22, 2023

(30) Foreign Application Priority Data
Oct. 13, 2023 (TW) 112139075

(51) Int. Cl. H03F 1/30; H03F 3/19; H03F 3/24

(52) U.S. Cl. CPC H03F 1/30; H03F 3/19; H03F 3/245; H03F 2200/451

(57) ABSTRACT

A radio frequency circuit includes an amplifier circuit and a bias circuit. The amplifier circuit is configured to receive a bias signal and amplify a radio frequency signal. The bias circuit is coupled to the amplifier circuit, and is configured to provide the bias signal. The bias circuit includes a transistor and a resistor. The transistor is arranged near the amplifier circuit. The resistor is arranged near the amplifier circuit, and a first terminal of the resistor is coupled to a transmission line, and a second terminal of the resistor is coupled to a control terminal of the transistor. An interference signal is coupled to the transmission line. The resistor is located between the transistor and the transmission line.

### TECHNICAL FIELD

The present invention relates to radio frequency circuits, and in particular, to a radio frequency circuit providing temperature compensation.

### BACKGROUND

A radio frequency (RF) circuit is a circuit that processes RF signals. RF circuits include power amplifiers that amplify RF signals to be transmitted over long distances. The RF circuits are widely used in various communication devices such as mobile phones, tablet computers, base stations, Wi-Fi access points, Bluetooth transceivers, and network devices.

As the demand for miniaturization and high power of RF circuits increases, the heat dissipation problem of the RF circuits becomes considerable, decreasing the threshold voltage of the transistors in the power amplifier, increasing the output power, and increasing the heat generation, thereby deteriorating the circuit performance.

### SUMMARY

According to an embodiment of the invention, a radio frequency circuit includes an amplifier circuit and a bias circuit. The amplifier circuit is configured to receive a bias signal and amplify a radio frequency signal. The bias circuit is coupled to the amplifier circuit, and is configured to provide the bias signal. The bias circuit includes a transistor and a resistor. The transistor is arranged near the amplifier circuit. The resistor is arranged near the amplifier circuit, and includes a first terminal coupled to a transmission line, and a second terminal coupled to a control terminal of the transistor. An interference signal is coupled to the transmission line, and the resistor is located between the transistor and the transmission line.

### BRIEF DESCRIPTION OF THE DRAWINGS

FIG. 1 is a schematic diagram of a radio frequency (RF) circuit according to an embodiment of the invention.

FIG. 2 is a layout schematic of the RF circuit in FIG. 1.

FIG. 3A shows the relationship of the output current signal and the output power of the power amplifier circuit.

FIG. 3B is a schematic diagram of the input signal and the output signal of the power amplifier circuit.

FIG. 4 is a schematic diagram of an RF circuit according to another embodiment of the invention.

FIG. 5 is a schematic diagram of an RF circuit according to another embodiment of the invention.

FIG. 6 is a schematic diagram of an RF circuit according to another embodiment of the invention.

### DETAILED DESCRIPTION

Below, exemplary embodiments will be described in detail with reference to accompanying drawings so as to be easily realized by a person having ordinary knowledge in the art. The inventive concept may be embodied in various forms without being limited to the embodiments set forth herein. Descriptions of well-known parts are omitted for clarity, and like reference numerals refer to like elements throughout.

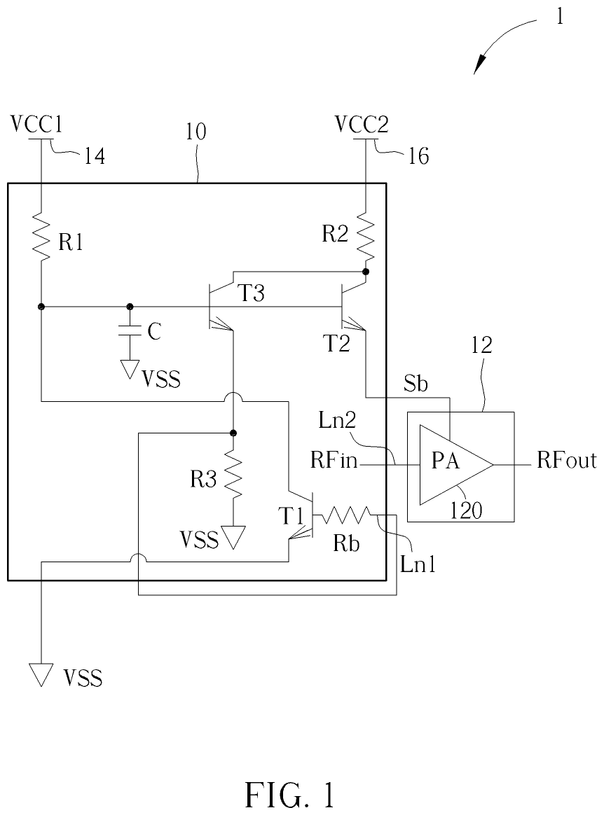

FIG. 1 is a schematic diagram of a radio frequency (RF) circuit 1 according to an embodiment of the invention. The RF circuit 1 may be a power amplifier to amplify an RF signal RFin and output an amplified RF signal RFout.

The RF circuit 1 may include a bias circuit 10 and an amplifier circuit 12. The bias circuit 10 may be coupled to the amplifier circuit 12 and provide a bias signal Sb for the amplifier circuit 12 to operate normally. The bias signal Sb may be a current signal. The amplifier circuit 12 may receive the bias signal Sb and amplify the RF signal RFin to generate the amplified RF signal RFout. Since the amplifier circuit 12 generates heat during operation, the temperature of the amplifier circuit 12 may increase, and the bias circuit 10 may detect the temperature change and modify the bias signal Sb accordingly, thereby adjusting the output power of the amplifier circuit 12, reducing heat dissipation, and stabilizing the operation of the RF circuit 1.

The bias circuit 10 may include a transistor T1 and a resistor Rb. The transistor T1 may serve as a temperature sensor, and the transistor T1 may be disposed near the amplifier circuit 12 to detect the temperature of the amplifier circuit 12. The threshold voltage of the transistor T1 and the current at the first terminal of the transistor T1 vary with the temperature. The threshold voltage of the transistor T1 is complementary to the absolute temperature (CTAT), The current at the first terminal of the transistor T1 is proportional to the absolute temperature (PTAT). When the temperature rises, the threshold voltage of the transistor T1 may be decreased. Thus the temperature can be detected.

The resistor Rb may be used for current limiting and voltage stabilization, thereby increasing the current stability of the bias circuit 10. In addition, the resistor Rb may be disposed near the amplifier circuit 12 to reduce the magnitude of adjacent interference signals. In the embodiment, a first terminal of the resistor Rb is coupled to a transmission line Ln1, and a second terminal of the resistor Rb is coupled to the control terminal of the transistor T1. The resistor Rb may be located between the transistor T1 and the transmission line Ln1. An interference signal may be coupled to the transmission line Ln1. When the interference signal is coupled to the transmission line Ln1, the resistor Rb may reduce the magnitude of the interference signal at the second terminal of the resistor Rb, thereby reducing the impact of the interference signal on the voltage at the control terminal of the transistor T1, ensuring accurate temperature detection of the amplifier circuit 12 by the transistor T1. The resistance of the resistor Rb is configured to be sufficiently large to reduce the magnitude of the interference signal, for example, the resistance may be greater than or equal to 300 ohms (Ω). In some embodiments, the resistor Rb may be replaced by a first resistor and a second resistor coupled in series. The first resistor may be disposed near the amplifier circuit 12, and the second resistor may be disposed far away from the amplifier circuit 12. The first resistor may be greater than or equal to 300 ohms, e.g., the first resistor may be 300 ohms, and the second resistor may be 200 ohms.

The amplifier circuit 12 may include an amplifier 120 such as a power amplifier (PA), and the bias circuit 10 may be coupled to the amplifier 120 and provide the bias signal Sb to the amplifier 120. The transmission line Ln1 may be located between the resistor Rb and an interference source. The interference source may be a power amplifier or a signal source. The interference source may be coupled to a transmission line Ln2, and the transmission line Ln2 may not be directly coupled to the transmission line Ln1. Since the RF signal RFin is a high-frequency high-power signal, the amplifier 120 may form an interference source that generate an interference signal including the RF signal RFin. The amplifier 120 may be coupled to the transmission line Ln2 that transmits the RF signal RFin, the interference signal may be coupled from the transmission line Ln2 to the transmission line Ln1, and the resistor Rb may reduce the magnitude of interference signal, thereby reducing the impact of the interference signal on the voltage at the control terminal of the transistor T1. In some embodiments, the interference signal may further include the amplified RF signal RFout. Further, if the distance between the transmission line Ln2 and the transmission line Ln1 is, for example, less than 3 micrometers (μm), the interference signal may be easily coupled from the transmission line Ln2 to the transmission line Ln1.

The bias circuit 10 may further include a capacitor C, a resistor R1, and a resistor R2. The resistor R1 includes a first terminal coupled to a bias supply 14, and a second terminal. The bias supply 14 may be external to the RF circuit 1 and may provide a fixed voltage VCC1 such as 2.8V. The resistor R2 includes a first terminal coupled to a bias supply 16, and a second terminal. The bias supply 16 may be external to the RF circuit 1 and may provide a fixed voltage VCC2 such as 5V. The first terminal of the transistor T1 is coupled via the resistor R1 to the bias supply 14, and the second terminal of the transistor T1 is coupled to a reference voltage terminal. The reference voltage terminal may provide a ground voltage such as 0V. The resistors R1 and R2 may have fixed resistances and may limit the current to achieve current stability. The resistance of the resistor R1 may be between 200 ohms and 400 ohms, and the resistance of the resistor R2 may be between 200 ohms and 400 ohms. In some embodiments, the resistors R1 and R2 may be removed from the bias circuit 10. The capacitor C may be used for voltage stabilization to increase the current stability of the bias circuit 10. The capacitor C includes a first terminal coupled to the second terminal of the resistor R1, and a second terminal coupled to the reference voltage terminal.

The bias circuit 10 may further include a transistor T2. The transistor T2 includes a control terminal, a first terminal and a second terminal, wherein the control terminal of the transistor T2 is coupled to the first terminal of the transistor T1 and the bias supply 14 (for example, the control terminal of the transistor T2 is coupled between the first terminal of the transistor T1 and the second terminal of the resistor R1, and coupled to the bias supply 14 via the resistor R1), the first terminal of the transistor T2 is coupled to the bias supply 16 via the resistor R2; and the second terminal of the transistor T2 is coupled to the amplifier circuit 12 to provide the bias signal Sb thereto.

The RF circuit 1 may further include a resistor R3 and a transistor T3. The transistor T3 includes a control terminal coupled to the second terminal of the resistor R1, a first terminal coupled to the second terminal of the resistor R2 and the first terminal of the transistor T2, and a second terminal coupled to the first terminal of the resistor Rb. The transmission line Ln1 may be located between the transistor T3 and the resistor Rb. The resistor R3 includes a first terminal coupled to the second terminal of the transistor T3, and a second terminal coupled to the reference voltage terminal (providing the voltage VSS). The resistor R3 may be used for current limiting, increasing the current stability of the bias circuit 10. In addition, the sum of the threshold voltage of the transistor T1 and the threshold voltage of the transistor T3 may establish the voltage at the control terminal of the transistor T2. For example, if the threshold voltages of the transistor T3 and the transistor T1 are both 0.65V, then the voltage at the control terminal of the transistor T2 is 1.3 (=0.65+0.65) V, and thus the transistor T2 is turned on to generate the bias signal Sb. The amplifier circuit 12 may generate heat during operation, decreasing the threshold voltage of the adjacent transistor T1, and decreasing the voltage of the control terminal of the transistor T2, thereby reducing the bias signal Sb. For example, if the threshold voltage of the transistor T1 drops to 0.6V, the voltage at the control terminal of the transistor T2 will drop to 1.25 (=0.6+0.65) V, decreasing the bias signal Sb accordingly, thereby reducing the output power of the amplifier 120 and reducing the heat dissipation to stabilize the operation of the RF circuit 1.

In some embodiments, the transistor T3 may further be disposed near the amplifier circuit 12. As the temperature of the amplifier circuit 12 increases, the threshold voltage of the adjacent transistor T3 may further decrease to further enhance the temperature detection. For example, if the threshold voltage of the transistor T1 drops to 0.6V and the threshold voltage of the transistor T3 drops to 0.6V, and thus the voltage at the control terminal of the transistor T2 drops to 1.2V (=0.6+0.6), further decreasing the bias signal Sb, reducing more output power and generating less heat at the amplifier 120 to further stabilize the operation of the RF circuit 1. In some embodiments, the transistor T3 may be disposed at a position non-overlapping with the transmission line Ln2 or at a suitable distance from the transmission line Ln2, so as to prevent the interference signal from affecting the voltage at the control terminal of the transistor T3, thereby increasing the accuracy of temperature detection.

The transistor T2 may be placed far away from the position of the resistor Rb, for example, a position far away from the resistor Rb relative to another component, or a position at an appropriate distance from the resistor Rb. A first distance between the transistor T1 and the resistor Rb may be less than a second distance between the transistor T2 and the resistor Rb. The ratio of the second distance to the first distance is greater than 20. For example, the first distance may be 3 μm˜5 μm, and the second distance may be 100 μm˜150 μm.

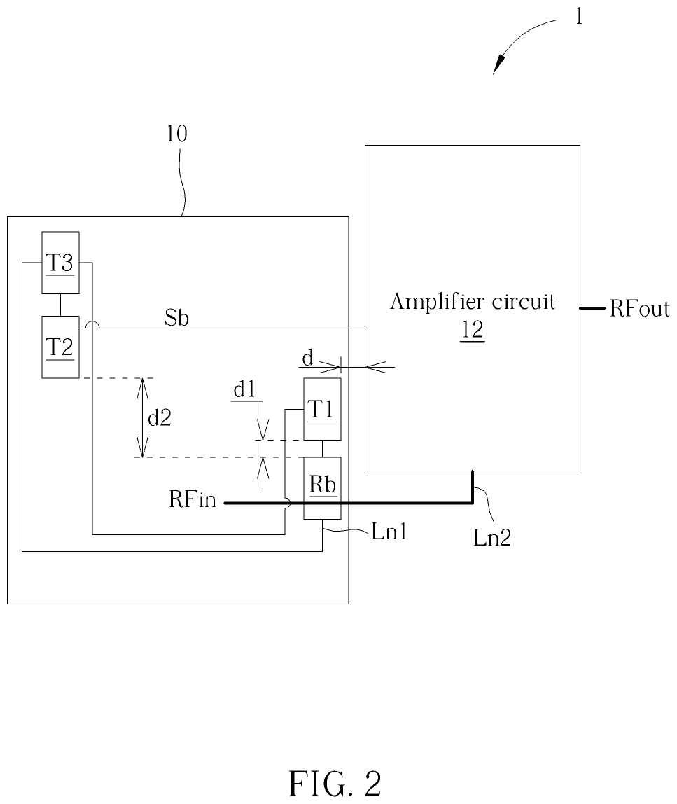

FIG. 2 is a layout schematic of the RF circuit 1. The transistor T1 and the resistor Rb may be placed near the amplifier circuit 12, the transistor T2 may be placed farther away from the amplifier circuit 12. The distance d between the transistor T1/resistor Rb and the amplifier circuit 12 may be 5 μm. The resistor Rb and the transmission line Ln2 may be disposed on the same layer or on different layers (that is, the resistor Rb may overlap with the transmission line Ln2).

The distance d1 between the transistor T1 and the resistor Rb may be less than the distance d2 between the transistor T2 and the resistor Rb.

If the interference signal including the RF signal RFin is coupled to the transmission line Ln1 and/or the resistor Rb, the resistor Rb may reduce the magnitude of the interference signal, thereby increasing the accuracy of temperature detection and achieving temperature compensation of the amplifier circuit 12.

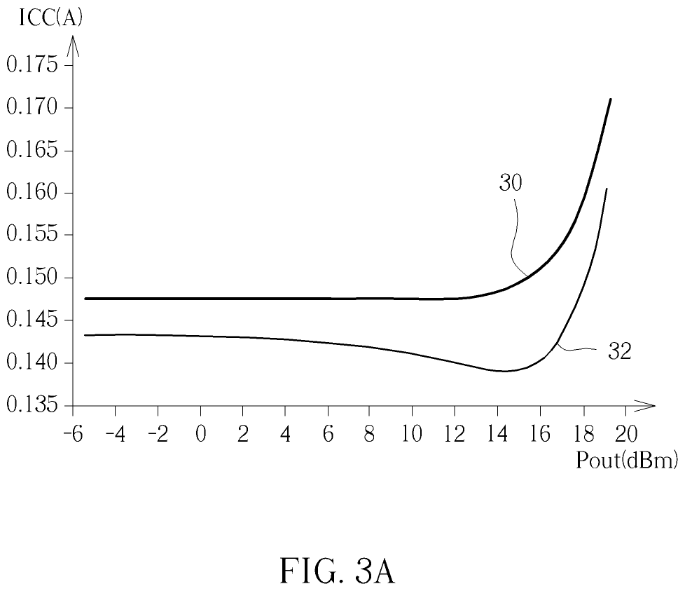

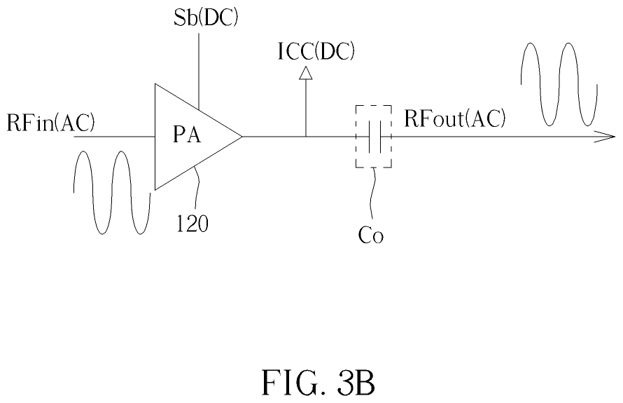

FIG. 3A shows the relationship of the output current signal and the output power of the power amplifier circuit, where the horizontal axis represents the output power Pout in decibel relative to one milliwatt (dBm), and the vertical axis represents the output current signal ICC in Ampere, (A). The output current signal ICC is a direct current (DC) current signal as shown in FIG. 3B. FIG. 3B is a schematic diagram of the power amplifier circuit including the input signal and the output signal. In FIG. 3A, Line 30 represents the output current signal ICC in the embodiment of the invention, and Line 32 represents an output current signal in the related art where the resistor Rb is not placed near the amplifier circuit 12. Line 30 shows that when the output power is 4˜16 dbm, the absolute value of the current change rate of the output current signal ICC is less than 2% in the embodiment of the invention. Line 32 shows that when the output power is 4 to 16 dbm, the absolute value of the current change rate of the output current signal is approximate 3% in the related art, exceeding the current change rate in the embodiment of the invention (3%>2%). In addition, Line 30 shows that when the output power is 4 to 16 dbm, the current change rate of the output current signal ICC is greater than 0%, indicating that the supply current is normal in the embodiment of the invention. Line 32 shows that when the output power is 4˜16 dbm, the current change rate of the output current signal may be less than 0%, indicating that the output current signal decreases and the supply current is insufficient in the related art, which is undesirable. In FIG. 3B, the amplifier 120 may output an amplified signal including a DC component and the amplified RF signal RFout. The amplified RF signal RFout may be an alternating current (AC) signal. The DC component may be positively correlated to the output current signal ICC. A DC blocking capacitor Co may receive the amplified signal from the amplifier 120, and remove the DC components while passing the amplified RF signal RFout, and the output current signal ICC may flow to the reference voltage terminal.

The transistors T1 to T3 may be, for example, N-type bipolar junction transistors (BJT), the control terminal being the base terminal, the first terminal being the collector terminal, and the second terminal being the emitter terminal. In some embodiments, the transistors T1 to T3 may be, but are not limited to, N-type metal-oxide-semiconductor field-effect transistors (MOSFET), the control terminal being the gate terminal, the first terminal being the drain terminal, and the second terminal being the source terminal.

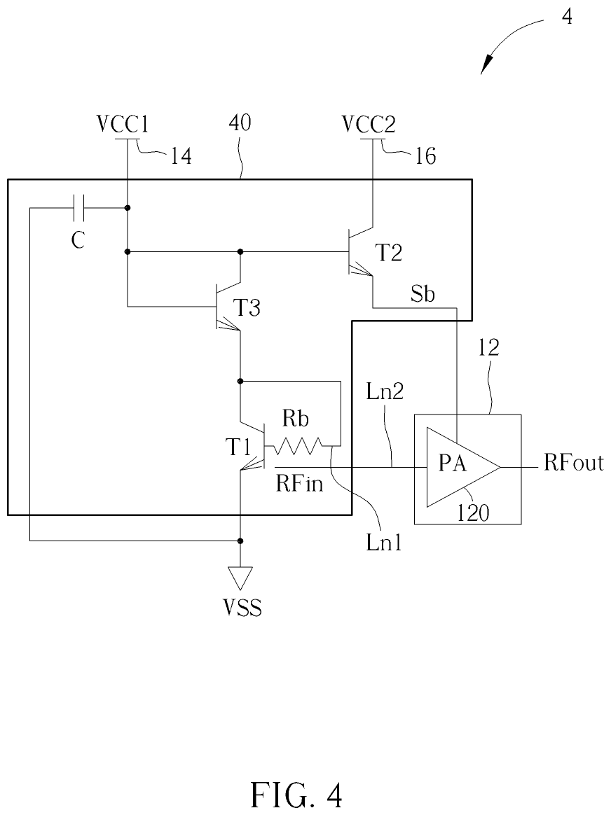

FIG. 4 is a schematic diagram of an RF circuit 4 according to another embodiment of the invention. The RF circuit 4 and the RF circuit 1 are different in the connections of the transistors T1 to T3. The connections of the transistors T1 to T3 in FIG. 4 are explained as follows. The connections and operations of other components in the RF circuit 4 are similar to the RF circuit 1, and will not be repeated here.

The transistor T1 includes a control terminal coupled to the second terminal of the resistor Rb, a first terminal coupled to the first terminal of the resistor Rb, and a second terminal coupled to the second terminal of the capacitor C. The transistor T3 includes a control terminal coupled to the bias supply 14, a first terminal coupled to the control terminal of the transistor T3 and the control terminal of the transistor T2, and a second terminal coupled to the first terminal of the resistor Rb. The transistor T2 includes a control terminal coupled to the first terminal of the transistor T3 and the bias supply 14, a first terminal coupled to the bias supply 16, and a second terminal coupled to the amplifier 120 to provide the bias signal Sb.

The transistor T1 and the resistor Rb may be placed near the amplifier 120 to reduce the magnitude of the interference signal, increasing the accuracy of temperature detection and achieving temperature compensation of the amplifier 120.

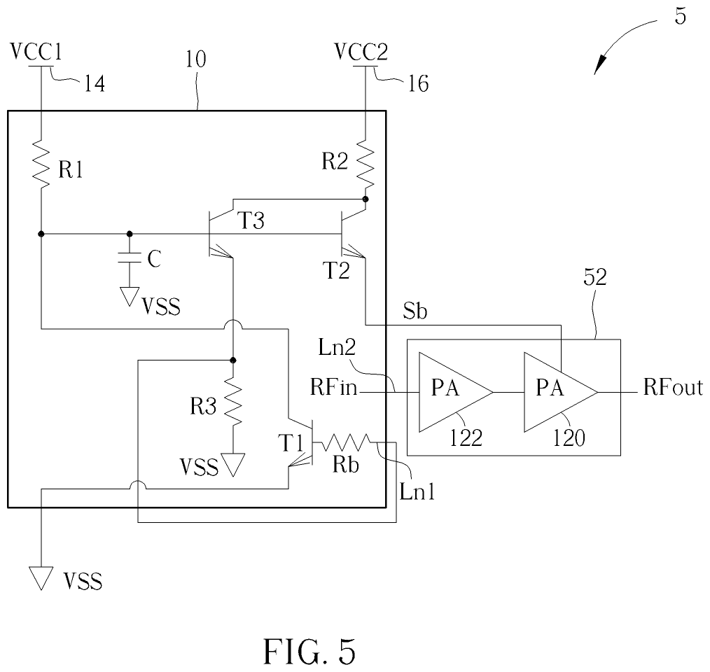

FIG. 5 is a schematic diagram of an RF circuit 5 according to another embodiment of the invention. The RF circuit 5 and the RF circuit 1 are different in that the amplifier circuit 52 includes amplifier 120 and amplifier 122 coupled to each other. The connections and operations of other components in the RF circuit 5 are similar to the RF circuit 1, and will not be repeated here. The explanations are now provided for the amplifier 120 and the amplifier 122.

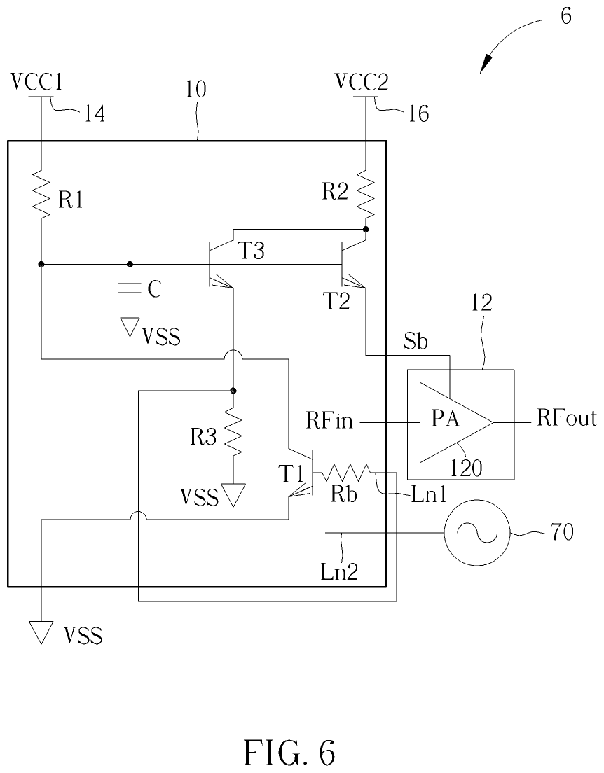

The bias circuit 10 may be coupled to the amplifier 120 and may provide the bias signal Sb to the amplifier 120. The amplifier 122 may be a preamplifier preceding the amplifier 120, and the amplifier 122 may form an interference source generating the interference signal. In other embodiments, the amplifier 122 may be an amplifier other than the amplifier circuit 12 as in FIG. 6. For example, the interference source 70 in FIG. 6 may be an external amplifier 122. Further, regardless the amplifier 122 being a preamplifier preceding the amplifier 120 or an amplifier other than the amplifier circuit 12, the transmission line Ln1 is located between the resistor Rb and the amplifier 122, the amplifier 122 is coupled to the transmission line Ln2, and the transmission line Ln2 is not directly coupled to the transmission line Ln1.

The transistor T1 and the resistor Rb may be placed near the amplifier 122 to reduce the magnitude of the interference signal, increasing the accuracy of temperature detection and achieving temperature compensation of the amplifier 120.

FIG. 6 is a schematic diagram of an RF circuit 6 according to another embodiment of the invention. The RF circuit 6 and the RF circuit 1 are different in that the transistor T1 and the resistor Rb are arranged near another interference source 70 in the RF circuit 6. The connections and operations of other components in the RF circuit 6 are similar to the RF circuit 1, and will not be repeated here. Explanations are now provided for the interference source 70.

The interference source 70 may be an amplifier other than the other amplifier circuits, or a signal sources generating or transmitting a high-frequency signal. In some embodiments, the RF circuit 6 may further include the interference source 70. The interference source 70 may be an amplifier other than the amplifier circuit 12, or an RF component such as an oscillator. The interference source 70 generating the interference signal is not coupled to the bias circuit 10. The transistor T1 and the resistor Rb may be arranged near the interference source 70 and/or the amplifier circuit 12 to reduce the magnitude of the interference signal, increasing the accuracy of temperature detection and achieving temperature compensation of the amplifier 120.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A radio frequency (RF) circuit comprising:
an amplifier circuit configured to receive a bias signal and amplify an RF signal; and
a bias circuit coupled to the amplifier circuit and configured to provide the bias signal, the bias circuit comprising:
a first transistor disposed near the amplifier circuit, and
a first resistor disposed near the amplifier circuit, the first resistor comprising a first terminal coupled to a first transmission line, and a second terminal coupled to a control terminal of the first transistor, wherein an interference signal is coupled to the first transmission line, and the first resistor is located between the first transistor and the first transmission line.

2. The RF circuit of claim 1, wherein a first terminal of the first transistor is coupled to a first bias supply, and a second terminal of the first transistor is coupled to a reference voltage terminal.

3. The RF circuit of claim 2, wherein a current at the first terminal of the first transistor varies with temperature.

4. The RF circuit of claim 2, further comprising a second transistor, a second terminal of the second transistor being coupled to the amplifier circuit, and the second transistor being configured to provide the bias signal to the amplifier circuit.

5. The RF circuit of claim 4, further comprising a third transistor comprising:
a control terminal coupled to the first bias supply and a control terminal of the second transistor;
a first terminal; and
a second signal terminal coupled to the first terminal of the first resistor.

6. The RF circuit of claim 5, wherein the third transistor is disposed near the amplifier circuit.

7. The RF circuit of claim 5, wherein a first terminal of the second transistor is coupled to a second bias supply.

8. The RF circuit of claim 5, wherein the control terminal of the second transistor is coupled to the first bias supply.

9. The RF circuit of claim 5, wherein a first distance between the first transistor and the first resistor is less than a second distance between the second transistor and the first resistor.

10. The RF circuit of claim 9, wherein the ratio of the second distance to the first distance is greater than 20.

11. The RF circuit of claim 5, wherein the first terminal of the third transistor is coupled to a first terminal of the second transistor or the control terminal of the second transistor.

12. The RF circuit of claim 1, wherein resistance of the first resistor is greater than or equal to 300 ohms (Ω).

13. The RF circuit of claim 1, wherein the first resistor is configured to reduce the magnitude of the interference signal at the second terminal of the first resistor.

14. The RF circuit of claim 1, wherein the interference signal comprises the RF signal or an amplified RF signal.

15. The RF circuit of claim 1, wherein the amplifier circuit comprises a first amplifier, the bias circuit is coupled to the first amplifier and provides the bias signal to the first amplifier, and the first amplifier forms an interference source generating the interference signal.

16. The RF circuit of claim 1, wherein the amplifier circuit comprises a first amplifier and a second amplifier coupled thereto, the bias circuit is coupled to the first amplifier and provides the bias signal to the first amplifier, the second amplifier is a preamplifier preceding the first amplifier, and the second amplifier forms an interference source generating the interference signal.

17. The RF circuit of claim 1, further comprising a second amplifier not coupled to the bias circuit, wherein the second amplifier forms an interference source generating the interference signal.

18. The RF circuit of claim 1, wherein the first transmission line is located between the first resistor and an interference source generating the interference signal, and the interference source is coupled to a second transmission line not directly coupled to the first transmission line.

19. The RF circuit of claim 1, wherein when the power of the bias signal is 4˜16 dBm, an absolute value of a current change rate of the bias signal is less than 2%.

20. The RF circuit of claim 1, wherein when the power of the bias signal is 4˜16 dBm, a current change rate of the bias signal is greater than 0%.
